(19) United States
(12) Patent Application Publication
(10) Pub. No.: US 2023/0275395 A1
(43) Pub. Date: Aug. 31, 2023

(54) METHOD FOR USE IN MANUFACTURING AN OPTICAL EMITTER ARRANGEMENT

(71) Applicant: ams Sensors Singapore Pte. Ltd., Singapore (SG)

(72) Inventors: Uros MARKOVIC, Eindhoven (NL); Lorenzo TONSA, Eindhoven (NL); James EILERTSEN, Eindhoven (NL)

(73) Assignee: ams Sensors Singapore Pte. Ltd., Singapore (SG)

(21) Appl. No.: 18/003,480

(22) PCT Filed: Jun. 16, 2021
(86) PCT No.: PCT/SG2021/050352

§ 371 Date: Dec. 27, 2022

(30) Foreign Application Priority Data
Jun. 30, 2020 (GB) 2009972.7

(51) Int. Cl. H01S 5/02257; H01S 5/183; H01L 33/58; H01L 33/00; H01S 5/0236

(52) U.S. Cl. CPC H01S 5/02257; H01S 5/183; H01L 33/58; H01L 33/005; H01S 5/0236; H01S 5/02345

(57) ABSTRACT

A method for use in manufacturing an optical emitter arrangement comprises holding an electrically conductive base member and two electrically conductive base elements in a predetermined spatial relationship, and providing two electrically conductive projections, wherein each projection extends in a direction away from a surface of a corresponding one of the base elements and wherein each projection terminates at a corresponding outer end. The method further comprises bringing a projecting portion of a surface profile of a mold tool into engagement with an area of a surface of the base member whilst bringing other portions of the surface profile of the mold tool into engagement with the outer ends of the projections so as to form a void that extends away from the surface of the base member around the projecting portion of the surface profile of the mold tool and that extends away from the surface of each of the base elements around each projection without extending over the outer end of each projection. The method further comprises injecting an electrically insulating plastic material into the void and curing the plastic material so as to form an electrically insulating housing that extends away from the surface of the base member so as to define a space for accommodating an optical emitter device, wherein the space extends away from the area of the surface of the base member, and wherein the housing also extends away from the surface of each of the base elements around each projection without covering the outer end of each projection. The method may be used, in particular though not exclusively, for manufacturing an optical emitter arrangement for a projector or an illuminator such as flood illuminator.

### FIELD

The present disclosure relates to method for use in manufacturing an optical emitter arrangement for use, in particular though not exclusively, in projectors or illuminators such as flood illuminators for mobile electronic devices.

### BACKGROUND

Optical emitter arrangements are known for use in projectors or illuminators such as flood illuminators for mobile electronic devices. Such optical emitter arrangements typically include an optical emitter device such as a VCSEL located within a housing, and an optical system including an optical element such as an optical diffuser, a lens or a lens array, fixed relative to the housing so that the optical element can transmit at least a portion of the light emitted by the optical emitter device out of the housing. The optical emitter device and the optical element are held in a fixed spatial relationship relative to one another so that the emitted light which is incident on the optical element has a desired or predetermined optical field at the optical element for optimum optical performance of the optical emitter arrangement. More specifically, the optical emitter device is typically mounted on a generally planar lead frame which is attached to the housing. The optical system includes an optical substrate, wherein the optical element is defined on, or by, the optical substrate, and wherein the optical substrate is also attached to the housing so that the optical emitter device and the optical element are held in the fixed spatial relationship relative to one another.

For some optical emitter arrangements, the optical emitter device may emit light which may be harmful (e.g. not eye-safe) to a person in the vicinity of the optical emitter arrangement if the emitted light is incident directly on the person without first being transmitted through the optical element. For example, the time-averaged optical power or the time-averaged optical intensity of the light emitted by the optical emitter device may be so high as to be harmful to a person if the emitted light is incident directly on the person or the peak optical power or the peak optical intensity of the light emitted by optical emitter device at any instant in time may be so high as to be harmful to a person if the emitted light is incident directly on the person. Consequently, optical emitter arrangements are known which incorporate an optical safety system, sometimes referred to as a cut-off or interlock system, which includes a controller and an electrically conductive circuit that extends from the controller to the optical substrate. In the event that the optical substrate moves relative to the housing, for example because the optical substrate becomes detached from the housing or damaged, the electrically conductive circuit is broken, the controller detects the break in the electrically conductive circuit, and the controller shuts off the supply of electrical power and/or electrical current to the optical emitter device thereby preventing the optical emitter device from emitting light which may cause harm to a person if the emitted light is incident directly on the person.

Such known optical emitter arrangements require an electrically conductive connection of some kind between the optical substrate and the housing to enable the electrically conductive circuit between the controller and the optical substrate. For example, a generic optical emitter arrangement generally designated 1 is shown in FIGS. 1A and 1B. As shown in FIG. 1B, the optical emitter arrangement 1 includes an electrically conductive base member 2, two electrically conductive base elements 3, and two electrically conductive pins or pillars 4, each pin or pillar 4 extending upwardly away from, and connected electrically to, a corresponding base element 3. The base member 2 and the two electrically conductive base elements 3 together constitute a base arrangement in the form of a lead frame generally designated 5. The base member 2, the two electrically conductive base elements 3, and the two electrically conductive pins or pillars 4 are typically formed from copper. The optical emitter arrangement 1 further includes an electrically insulating housing 12 and an optical emitter device such as a VCSEL 16 located within the housing 12. A lower side of the VCSEL 16 is electrically connected to the electrically conductive base member 2 by electrically conductive adhesive 18. An upper side of the VCSEL 16 is electrically connected to a first one of the electrically conductive base elements 3 by wire bonds 20.

The optical emitter arrangement 1 further includes an optical system 30 which includes an optical substrate 32, an optical safety element 34 attached to an underside of the optical substrate 32, and an optical element in the form of an optical diffuser 36 attached to an underside of the optical safety element 34. The optical safety element 34 includes an electrically conductive track or trace 40 covered by an electrically insulating coating 42. The optical diffuser 36 is attached to the underside of the optical safety element 34 so that the electrically conductive track or trace 40 extends around, or generally coincides with, a periphery of the optical diffuser 36 so as to define an aperture 44 for the transmission of light through the optical safety element 34. As will be described in more detail below, the ends of the electrically conductive track or trace 40 are connected electrically to the upper ends of the electrically conductive pins or pillars 4.

A prior art method for manufacturing the generic optical emitter arrangement 1 is illustrated in FIGS. 2A to 2F. The prior art method begins with the provision of the electrically conductive base member 2 and the electrically conductive base elements 3 held in a predetermined spatial relationship as shown in FIG. 2A. One of skill in the art will understand that the electrically conductive base member 2 and the electrically conductive base elements 3 are fixed to a surface (not shown in FIG. 2A) in the predetermined spatial relationship.

As shown in FIG. 2B, each electrically conductive pillar or pin 4 is attached to the corresponding electrically conductive base element 3 using electrically conductive adhesive 6 so that each pillar or pin 4 extends upwardly away from an upper surface of the corresponding base element 3 and terminates in an upper end 4a. A projecting portion 10a of a surface profile of a mold tool 10 is then brought into contact with an area 8 of an upper surface of the base member 2 as shown in FIG. 2C. The surface profile of the mold tool 10, the base member 2, the base elements 3 and the pillars or pins 4 define a void 13 that extends away from the upper surface of the base member 2 around the projecting portion 10a of the surface profile of the mold tool 10 and that extends away from the upper surface of each of the base elements 3 and around each pillar or pin 4, wherein the void 13 includes a gap 13a which extends over the upper ends 4a of the pillars or pins 4.

An electrically insulating plastic material is then injected into the void 13 and cured to form the electrically insulating housing 12 so that the housing 12 defines a space which extends away from the area 8 of the surface of the base member 2 and the housing 12 extends over the upper ends 4a and around the sides of the pillars or pins 4 as shown in FIG. 2D.

To enable the formation of an electrically conductive connection between the upper ends 4a of each pillar or pin 4 and the electrically conductive track or trace 40 of the optical safety element 34, the material of the housing 12 above the upper end 4a of each pillar or pin 4 is removed, for example by laser drilling, so as to define opening or window 14 in the housing 12 and thereby expose the upper end 4a of each pillar or pin 4 as shown in FIG. 2E.

As shown in FIG. 2F, a lower surface of the VCSEL 16 is bonded onto the area 8 of the upper surface of the base member 2 and wire-bonds 20 are formed from an upper surface of the VCSEL 16 to an upper surface of one of the base elements 3. Electrically conductive epoxy 50 is applied to the upper ends 4a of the pillars or pins 4 through the corresponding openings or windows 14 in the housing 12. One end of the track or trace 40 of the optical safety element 34 is aligned with the electrically conductive epoxy 50 applied to the upper end 4a of one pillar or pin 4 and the other end of the track or trace 40 is aligned with the electrically conductive epoxy 50 applied to the upper end 4a of the other pillar or pin 4. The optical system 30 is then attached to the housing 12 using adhesive (not shown in FIG. 2F) whilst also making an electrically conductive connection between each end of the track or trace 40 of the optical safety element 34 and the electrically conductive epoxy 50 applied to the upper end 4a of the corresponding pin or pillar 4.

A problem with such prior art methods for manufacturing prior art optical emitter arrangements is that the electrically conductive connection between the track or trace 40 of the optical safety element 34 and the pillars or pins 4 may be unreliable. For example, the openings or windows 14 in the housing 12 may not be fully opened due to tolerances of the laser drilling process used to form the openings or windows 14. The upper ends 4a of the pillars or pins 4 may be at least partially covered with residual housing material or debris from the laser drilling process. The openings or windows 14 in the housing 12 may be positioned inaccurately or may be inaccurate in size or shape relative to the upper ends 4a of the pillars or pins 4. The upper ends 4a of the pillars or pins 4 may be burned as a result of the laser drilling process.

### SUMMARY

According to an aspect of the present disclosure there is provided a method for use in manufacturing an optical emitter arrangement, the method comprising:
holding an electrically conductive base member and two electrically conductive base elements in a predetermined spatial relationship;
providing two electrically conductive projections, wherein each projection extends in a direction away from a surface of a corresponding one of the base elements and wherein each projection terminates at a corresponding outer end;
bringing a projecting portion of a surface profile of a mold tool into engagement with an area of a surface of the base member whilst bringing other portions of the surface profile of the mold tool into engagement with the outer ends of the projections so as to form a void that extends away from the surface of the base member around the projecting portion of the surface profile of the mold tool and that extends away from the surface of each of the base elements and around each projection without extending over the outer end of each projection;
injecting an electrically insulating plastic material into the void; and
curing the electrically insulating plastic material so as to form an electrically insulating housing that extends away from the surface of the base member so as to define a space for accommodating an optical emitter device, wherein the space extends away from the area of the surface of the base member, and wherein the housing also extends away from the surface of each of the base elements around each projection without covering the outer end of each projection.

As a consequence of the contact between the outer end of each projection and the surface profile of the mold tool, the plastic material is not able to penetrate between the outer end of each projection and the surface profile of mold tool during injection of the plastic material into the void. Consequently, when the plastic material is cured to form the housing, the outer end of each projection remains exposed. Such a method may be more reliable than prior art methods for use in manufacturing optical emitter arrangements because such a method may avoid any requirement to define an opening or window in the housing in order to expose the outer end of each projection after the electrically insulating housing material is cured and may therefore avoid the problems associated with defining such openings or windows in the housing.

Each projection may be deformable. For example, each projection may be resilient or plastic. Each projection may be compressed between the surface profile of the mold tool and the corresponding base element when the surface profile of the mold tool makes contact with the outer end of each projection. The use of deformable projections may reduce the likelihood that a gap is formed between the outer end of each projection and the surface profile of the mold tool when the projecting portion of the surface profile of the mold tool makes contact with the area of the surface of the base member. Thus, such a method may reduce the likelihood that any of the injected electrically insulating material covers the outer end of each projection.

Each projection may comprise, or be formed from, deformable electrically conductive material. The deformable electrically conductive material may be resilient or plastic.

Each projection may comprise a rigid electrically conductive pillar or pin and deformable electrically conductive material.

Deformable electrically conductive material may be located between a base end of the pillar or pin and the surface of the corresponding base element.

The method may comprise applying or dispensing deformable electrically conductive material to the surface of the corresponding base element and engaging the base end of each pillar or pin with the deformable electrically conductive material.

The method may comprise applying or dispensing deformable electrically conductive material to the base end of each pillar or pin and engaging the deformable electrically conductive material at the base end of each pillar or pin with the surface of the corresponding base element.

Each pillar or pin may be unitary with the corresponding base element or may be formed integrally or monolithically with the corresponding base element.

Deformable electrically conductive material may be located at, or may define, the outer end of each electrically conductive projection.

The method may comprise applying or dispensing deformable electrically conductive material to the outer end of each pillar or pin.

The deformable electrically conductive material may comprise a deformable electrically conductive adhesive material.

The deformable electrically conductive adhesive material may comprise silver epoxy.

The deformable electrically conductive adhesive material may be uncured or only partially cured when the surface profile of the mold tool makes contact with the outer end of each projection. This may make each projection deformable when each projection includes a rigid electrically conductive pillar or pin. Each projection may therefore be compressed when the surface profile of the mold tool makes contact with the outer end of each projection. The use of deformable projections and the compression of the projections between the surface profile of the mold tool and the corresponding base element when the surface profile of the mold tool makes contact with the outer end of each projection may reduce the likelihood that a gap is formed between the outer end of each projection and the surface profile of the mold tool when the projecting portion of the surface profile of the mold tool makes contact with the area of the surface of the base member. Thus, such a method may reduce the likelihood that any of the injected electrically insulating material covers the outer end of each projection.

The method may comprise curing the deformable electrically conductive adhesive material after the surface profile of the mold tool makes contact with the outer end of each projection.

The method may comprise curing the deformable electrically conductive adhesive material before curing the electrically insulating plastic material to form the electrically insulating housing.

The method may comprise separating the mold tool from the housing after curing the electrically insulating plastic material.

The method may comprise applying or dispensing electrically conductive adhesive material to the outer end of each projection after separating the mold tool from the housing.

The method may comprise providing an optical system comprising an optical substrate and an optical safety element attached to the optical substrate, the optical safety element including an electrically conductive track or trace.

The method may comprise bringing the optical system and the electrically conductive adhesive material at the outer end of each projection into engagement so that the electrically conductive track or trace makes contact with the electrically conductive adhesive material at the outer end of each projection.

The optical system may comprise an optical element attached to the optical safety element. The optical element may comprise an optical diffuser. The optical element may be configured to spatially modulate the light emitted by the optical emitter device. The optical element may be configured to spatially modulate the amplitude and/or phase of the light emitted by the optical emitter device. The optical element may be refractive. The optical element may comprise a lens. The optical element may comprise a microlens. The optical element may comprise a plurality of lenses. The optical element may comprise a microlens array. The optical element may be diffractive. The optical element may comprise a diffraction grating.

The method may comprise attaching the optical system to the housing.

The method may comprise attaching the optical system to the housing using an adhesive.

The optical emitter device may comprise a light emitting diode (LED) or a laser diode such as a vertical cavity surface emitting laser (VCSEL) diode.

The base member may comprise a metal such as copper.

Each of the base elements may comprise a metal such as copper.

Each of the projections may comprise a metal such as copper.

Each pillar or pin may comprise a metal such as copper.

The portions of the surface profile of the mold tool which are brought into engagement with the outer ends of the projections may be deformable. Each deformable portion of the surface profile of the mold tool may be compressed when the deformable portion of the surface profile of the mold tool is brought into engagement with the outer end of the corresponding projection.

The method may comprise holding more than one electrically conductive base member and more than two electrically conductive base elements in the predetermined spatial relationship. The method may comprise providing more than two electrically conductive projections.

The method may comprise holding one or more electrically conductive further base members and two or more electrically conductive further base elements in a predetermined spatial relationship relative to each other and relative to the base member and each of the base elements. The method may comprise providing two or more electrically conductive further projections, wherein each further projection extends in a direction away from a surface of a corresponding one of the further base elements and wherein each further projection terminates at a corresponding outer end. The method may comprise bringing a corresponding further projecting portion of the surface profile of the mold tool into engagement with a corresponding area of a surface of each of the further base members whilst bringing other portions of the surface profile of the mold tool into engagement with the outer ends of each of the further projections so that the void extends away from the surface of each of the further base members around each of the further projecting portions of the surface profile of the mold tool and the void extends away from the surface of each of the further base elements and around each further projection without extending over the outer end of each further projection. Injecting the electrically insulating plastic material into the void and curing the electrically insulating plastic material may form one or more further electrically insulating housings, wherein each further housing extends away from the surface of the corresponding further base member so as to define a further space for accommodating a further optical emitter device, wherein the further space extends away from the area of the surface of the corresponding further base member, and wherein each further housing also extends away from the surface of each of the corresponding further base elements around each of the corresponding further projections without covering the outer end of each further projection. Such a method may be used for the manufacture of one or more further optical emitter arrangements, for example simultaneously, or in parallel with, the manufacture of the optical emitter arrangement.

According to an aspect of the present disclosure there is provided an optical emitter arrangement manufactured according to the method for use in manufacturing an optical emitter arrangement as described above.

According to an aspect of the present disclosure there is provided a projector or an illuminator such as a flood illuminator, comprising the optical emitter arrangement as described above.

It should be understood that any one or more of the features of any one of the foregoing aspects of the present disclosure may be combined with any one or more of the features of any of the other foregoing aspects of the present disclosure.

### BRIEF DESCRIPTION OF THE DRAWINGS

Optical emitter arrangements will now be described by way of non-limiting example only with reference to the accompanying drawings of which:

FIG. 1A is a schematic perspective view of a generic optical emitter arrangement;

FIG. 1B is an exploded schematic view of the optical emitter arrangement of FIG. 1A;

FIG. 2A is a side view schematic of a first step of a prior art method for use in manufacturing the optical emitter arrangement of FIG. 1A;

FIG. 2B is a side view schematic of a second step of a prior art method for use in manufacturing the optical emitter arrangement of FIG. 1A;

FIG. 2C is a side view schematic of a third step of a prior art method for use in manufacturing the optical emitter arrangement of FIG. 1A;

FIG. 2D is a cross-sectional schematic of a fourth step of a prior art method for use in manufacturing the optical emitter arrangement of FIG. 1A;

FIG. 2E is a cross-sectional schematic of a fifth step of a prior art method for use in manufacturing the optical emitter arrangement of FIG. 1A;

FIG. 2F is a cross-sectional schematic of a sixth step of a prior art method for use in manufacturing the optical emitter arrangement of FIG. 1A;

FIG. 3A is a side view schematic of a first step of a first method for use in manufacturing the optical emitter arrangement of FIG. 1A;

FIG. 3B is a side view schematic of a second step of a first method for use in manufacturing the optical emitter arrangement of FIG. 1A;

FIG. 3C is a side view schematic of a third step of a first method for use in manufacturing the optical emitter arrangement of FIG. 1A;

FIG. 3D is a side view schematic of a fourth step of a first method for use in manufacturing the optical emitter arrangement of FIG. 1A;

FIG. 3E is a cross-sectional schematic of a fifth step of a first method for use in manufacturing the optical emitter arrangement of FIG. 1A;

FIG. 3F is a cross-sectional schematic of a sixth step of a first method for use in manufacturing the optical emitter arrangement of FIG. 1A;

FIG. 4A is a side view schematic of a first step of a second method for use in manufacturing the optical emitter arrangement of FIG. 1A;

FIG. 4B is a side view schematic of a second step of a second method for use in manufacturing the optical emitter arrangement of FIG. 1A;

FIG. 4C is a side view schematic of a third step of a second method for use in manufacturing the optical emitter arrangement of FIG. 1A;

FIG. 4D is a cross-sectional schematic of a fourth step of a second method for use in manufacturing the optical emitter arrangement of FIG. 1A; and

FIG. 4E is a cross-sectional schematic of a fifth step of a second method for use in manufacturing the optical emitter arrangement of FIG. 1A.

### DETAILED DESCRIPTION OF THE DRAWINGS

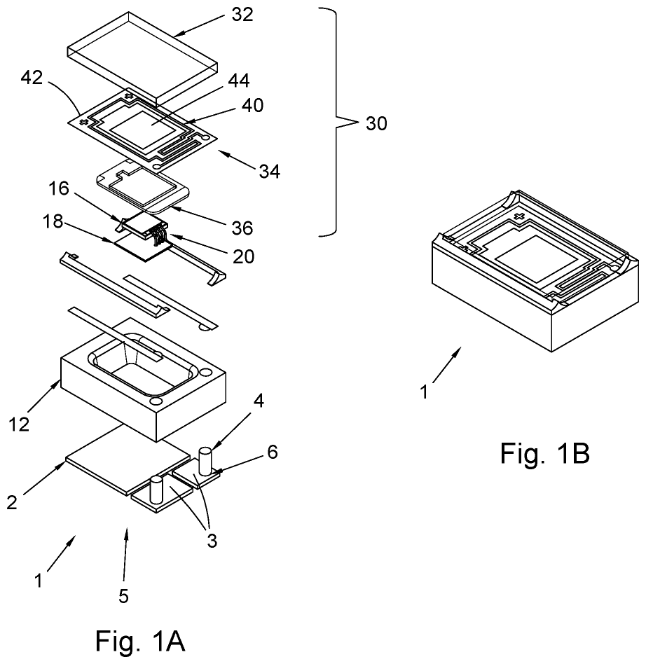

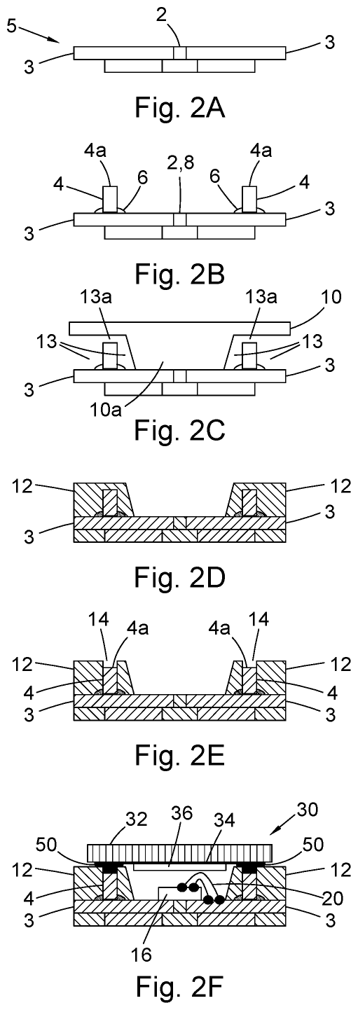

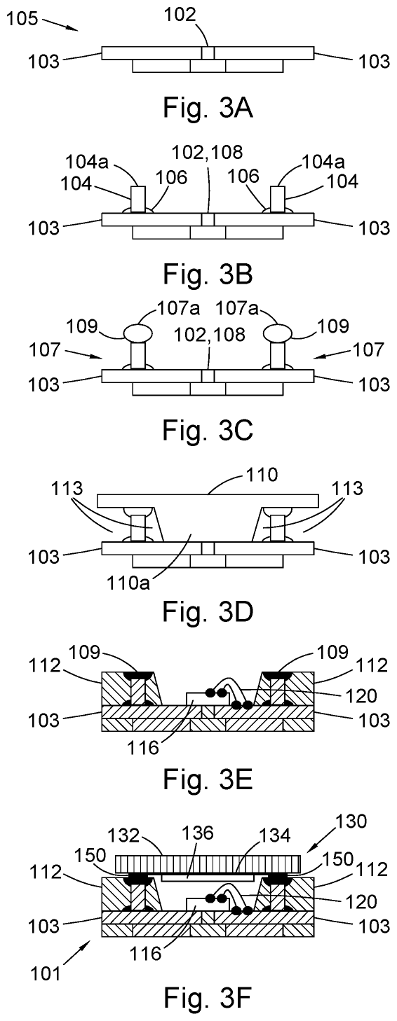

FIGS. 3A to 3F illustrate a first method for use in manufacturing an optical emitter arrangement 101 according to the present disclosure. It should be understood that the optical emitter arrangement 101 has features which are similar to those of the generic optical emitter arrangement 1 of FIGS. 1A and 1B and that like features of the optical emitter arrangement 101 are identified with the same reference numerals of the corresponding features of the generic optical emitter arrangement 1 of FIGS. 1A and 1B incremented by “100”. The method begins with the provision of an electrically conductive base member in the form of a copper base member 102 and two electrically conductive base elements in the form of two copper base elements 103 held in a predetermined spatial relationship as shown in FIG. 3A. It should be understood that the base member 102 and two electrically conductive base elements 103 shown may be similar or identical to the base member 2 and the two electrically conductive base elements 3 of the generic optical emitter arrangement 1 of FIGS. 1A and 1B. The electrically conductive base member 102 and the two electrically conductive base elements 103 together constitute a base arrangement in the form of a lead frame generally designated 105. One of skill in the art will understand that the electrically conductive base member 102 and the electrically conductive base elements 103 are fixed to a surface (not shown in FIG. 3A) in the predetermined spatial relationship.

As shown in FIG. 3B, an electrically conductive pillar or pin in the form of a copper pillar or pin 104 is attached to the corresponding electrically conductive base element 103 using electrically conductive adhesive in the form of silver epoxy 106. The silver epoxy 106 is applied to, or dispensed on, an upper surface of the corresponding base element 103 and a base end of the corresponding pillar or pin 104 is engaged with the silver epoxy 106. The silver epoxy 106 is then cured to fix each pillar or pin 104 relative to the corresponding base element 103 so that pillar or pin 104 extends upwardly away from an upper surface of the corresponding base element 103.

Electrically conductive adhesive in the form of silver epoxy 109 is applied to, or dispensed on, an outer or upper end 104a of each pillar or pin 104 as shown in FIG. 3C. Each pillar or pin 104, the corresponding silver epoxy 106 and the corresponding silver epoxy 109 together constitute an electrically conductive projection 107. Each electrically conductive projection 107 terminates in an outer or upper end 107a.

A projecting portion 110a of a surface profile of a mold tool 110 is then brought into contact with an area 108 of an upper surface of the base member 102 whilst other portions of the surface profile of a mold tool 110 are brought into contact with the uncured silver epoxy 109 at the outer or upper end 104a of each pillar or pin 104 so as to engage, compress and deform the uncured silver epoxy 109 between the surface profile of a mold tool 110 and the outer or upper end 104a of each pillar or pin 104 as shown in FIG. 3D. The surface profile of the mold tool 110, the lead frame 105, and the pillars or pins 104 define a void 113, wherein the void 113 extends away from the upper surface of the base member 102 around the projecting portion 110a of the surface profile of the mold tool 110 and wherein the void 113 extends away from the upper surface of each of the base elements 103 and around the sides of the pillars or pins 104. The silver epoxy 109 is then cured while the surface profile of the mold tool 110 remains in contact with the area 108 of the upper surface of the base member 102 and the silver epoxy 109 at the outer or upper end 104a of each pillar or pin 104.

An electrically insulating plastic material is then injected into the void 113 and cured to form an electrically insulating housing 112. As shown in cross-section in FIG. 3E, the housing 112 extends away from the upper surface of the base member 102 so as to define a space which extends upwardly away from the area 108 of the upper surface of the base member 102. The housing 112 also extends away from the upper surface of each of the base elements 103 around the sides of the pillars or pins 104, without covering the outer or upper ends 104a of the pillars or pins 104. The mold tool 110 is removed. A lower surface of a VCSEL 116 is then bonded onto the area 108 of the upper surface of the base member 102 using electrically conductive adhesive (not shown in FIG. 3E) and wire-bonds 120 are formed from an upper surface of the VCSEL 116 to an upper surface of one of the base elements 3.

As shown in cross-section in FIG. 3F, additional electrically conductive epoxy 150 is applied to the silver epoxy 109 at the outer or upper ends 104a of the pillars or pins 104. As will be described in more detail below, an optical system 130 is then attached to the housing 112. Like the optical system 30 of FIGS. 1A and 1B, the optical system 130 includes an optical substrate 132, an optical safety element 134 attached to an underside of the optical substrate 132, and an optical element in the form of an optical diffuser 136 attached to an underside of the optical safety element 134. The optical safety element 134 includes an electrically conductive track or trace (not shown in FIG. 3F) covered by an electrically insulating coating (not shown in FIG. 3F). The optical diffuser 136 is attached to the underside of the optical safety element 134 so that the electrically conductive track or trace extends around, or generally coincides with, a periphery of the optical diffuser 136 so as to define an aperture for the transmission of light through the optical safety element 134.

One end of an electrically conductive track or trace of the optical safety element 134 is aligned with the electrically conductive epoxy 150 at the outer or upper end 104a of one pillar or pin 104 and the other end of the electrically conductive track or trace is aligned with the electrically conductive epoxy 150 at the outer or upper end 104a of the other pillar or pin 104. The optical system 130 is then attached to the housing 112 using adhesive (not shown in FIG. 3F) whilst also making an electrically conductive connection between each end of the track or trace of the optical safety element 134 and the electrically conductive epoxy 150 at the outer or upper end 104a of the corresponding pin or pillar 104.

One of ordinary skill the art will understand that as a consequence of the contact between the silver epoxy 109 at the outer or upper end 104a of each pillar or pin 104 and the surface profile of the mold tool 110, the plastic material is not able to penetrate between the silver epoxy 109 and the surface profile of mold tool 110 during injection of the plastic material into the void 113. Consequently, when the plastic material is cured to form the housing 112, the silver epoxy 109 remains exposed at the outer or upper end 107a of each projection 107. Moreover, prior to curing the silver epoxy 109, the silver epoxy 109 is deformable in nature. Consequently, when the surface profile of the mold tool 110 makes contact with the uncured silver epoxy 109, the uncured silver epoxy 109 is compressed against the outer or upper end 104a of the corresponding pin or pillar 104. The compression of the uncured silver epoxy 109 when the surface profile of the mold tool 110 makes contact with the uncured silver epoxy 109 may reduce the likelihood that a gap is formed between the uncured silver epoxy 109 and the surface profile of the mold tool 110 when the projecting portion 110a of the surface profile of the mold tool 110 makes contact with the area 108 of the surface of the base member 102. Thus, such a method may reduce the likelihood that any of the injected electrically insulating plastic material covers the silver epoxy 109.

Such a method avoids any requirement to define or form any openings or windows in the housing 112 in order to expose the silver epoxy 109 at the outer or upper end 104a of each pillar or pin 104 after the electrically insulating plastic housing material is cured. Such a method may therefore be more reliable than prior art methods for use in manufacturing optical emitter arrangements which require the definition or formation of openings or windows in a housing in order to expose the outer or upper end of an electrically conductive pillar or pin after the electrically insulating plastic housing material is cured.

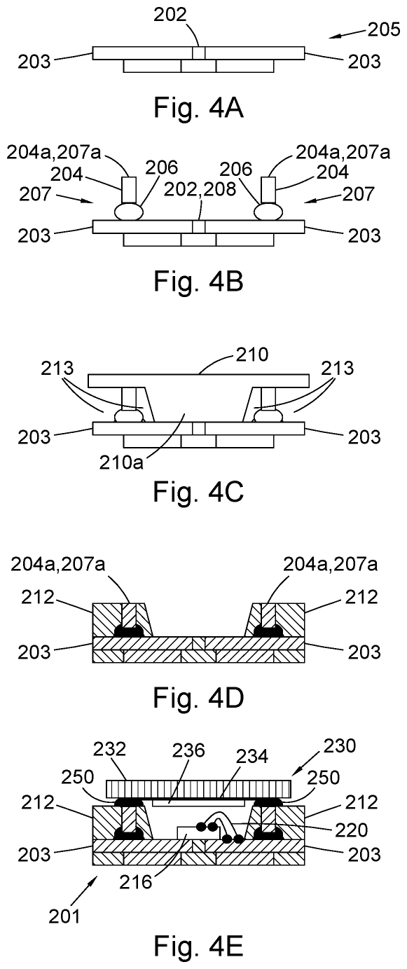

FIGS. 4A to 4E illustrate a second method for use in manufacturing an optical emitter arrangement 201 according to the present disclosure. It should be understood that the optical emitter arrangement 201 has features which are similar to those of the generic optical emitter arrangement 1 of FIGS. 1A and 1B and that like features of the optical emitter arrangement 201 are identified with the same reference numerals of the corresponding features of the generic optical emitter arrangement 1 of FIGS. 1A and 1B incremented by “200”. The method begins with the provision of an electrically conductive base member in the form of a copper base member 202 and two electrically conductive base elements in the form of two copper base elements 203 held a predetermined spatial relationship as shown in FIG. 4A. It should be understood that the base member 202 and two electrically conductive base elements 203 may be similar or identical to the base member 2 and the two electrically conductive base elements 3 of the generic optical emitter arrangement 1 of FIGS. 1A and 1B. The electrically conductive base member 202 and the two electrically conductive base elements 203 together constitute a base arrangement in the form of a lead frame generally designated 205. One of skill in the art will understand that the electrically conductive base member 202 and the electrically conductive base elements 203 are fixed to a surface (not shown in FIG. 4A) in the predetermined spatial relationship.

As shown in FIG. 4B, an electrically conductive pillar or pin in the form of a copper pillar or pin 204 is attached to the corresponding electrically conductive base element 203 using electrically conductive adhesive in the form of silver epoxy 206. The silver epoxy 206 is applied to, or dispensed on, an upper surface of the corresponding base element 203 and a base end of the corresponding pillar or pin 204 is engaged with the silver epoxy 206 so that pillar or pin 204 extends upwardly away from an upper surface of the corresponding base element 203. Each pillar or pin 204, and the corresponding silver epoxy 206 together constitute an electrically conductive projection 207. Each electrically conductive projection 207 terminates in an outer or upper end 207a.

A projecting portion 210a of a surface profile of a mold tool 210 is then brought into contact with an area 208 of an upper surface of the base member 202 whilst other portions of the surface profile of the mold tool 210 are brought into contact with the outer or upper end 204a of each pillar or pin 204 so as to engage, compress and deform the uncured silver epoxy 206 between the base end of each pillar or pin 204 and the corresponding base element 203 as shown in FIG. 4C. The surface profile of the mold tool 210, the lead frame 205, and the pillars or pins 204 define a void 213, wherein the void 213 extends away from the upper surface of the base member 202 around the projecting portion 210a of the surface profile of the mold tool 210 and wherein the void 213 extends away from the upper surface of each of the base elements 203 and around the sides of the pillars or pins 204. The silver epoxy 206 is then cured while the surface profile of the mold tool 210 remains in contact with the area 208 of the upper surface of the base member 202 and the outer or upper end 204a of each pillar or pin 204.

An electrically insulating plastic material is then injected into the void 213 and cured to form an electrically insulating housing 212. As shown in cross-section in FIG. 4D, the housing 212 extends away from the upper surface of the base member 202 so as to define a space which extends upwardly away from the area 208 of the upper surface of the base member 202. The housing 212 also extends away from the upper surface of each of the base elements 203 around the sides of the pillars or pins 204, without covering the outer or upper ends 204a of the pillars or pins 204 as shown in FIG. 4D.

The mold tool 210 is removed. As shown in cross-section in FIG. 4E, a lower surface of a VCSEL 216 is then bonded onto the area 208 of the upper surface of the base member 202 using electrically conductive adhesive (not shown in FIG. 4E) and wire-bonds 220 are formed from an upper surface of the VCSEL 216 to an upper surface of one of the base elements 203. Additional electrically conductive epoxy 250 is applied to the outer or upper end 204a of each pillar or pin 204. As will be described in more detail below, an optical system 230 is then attached to the housing 212. Like the optical system 30 of FIGS. 1A and 1B, the optical system 230 includes an optical substrate 232, an optical safety element 234 attached to an underside of the optical substrate 232, and an optical element in the form of an optical diffuser 236 attached to an underside of the optical safety element 234. The optical safety element 234 includes an electrically conductive track or trace (not shown in FIG. 4E) covered by an electrically insulating coating (not shown in FIG. 4E). The optical diffuser 236 is attached to the underside of the optical safety element 234 so that the electrically conductive track or trace extends around, or generally coincides with, a periphery of the optical diffuser 236 so as to define an aperture for the transmission of light through the optical safety element 234.

One end of an electrically conductive track or trace of the optical safety element 234 is aligned with the outer or upper end 204a of one pillar or pin 204 and the other end of the electrically conductive track or trace is aligned with the outer or upper end 204a of the other pillar or pin 204. The optical system 230 is then attached to the housing 212 using adhesive (not shown in FIG. 4E) whilst also making an electrically conductive connection between each end of the track or trace of the optical safety element 234 and the outer or upper end 204a of the corresponding pin or pillar 204.

One of ordinary skill the art will understand that as a consequence of the contact between the outer or upper end 204a of each pillar or pin 204 and the surface profile of the mold tool 210, the plastic material is not able to penetrate between the outer or upper end 204a of each pillar or pin 204 and the surface profile of the mold tool 210 during injection of the plastic material into the void 213. Consequently, when the plastic material is cured to form the housing 212, the outer or upper end 207a of each projection 207 remains exposed. Moreover, prior to curing the silver epoxy 206, the silver epoxy 206 is deformable in nature. Consequently, when the surface profile of the mold tool 210 makes contact with the outer or upper end 204a of each pillar or pin 204, the uncured silver epoxy 206 is compressed between the base end of the corresponding pin or pillar 204 and the surface of the corresponding base element 203. The compression of the uncured silver epoxy 206 when the surface profile of the mold tool 210 makes contact with the outer or upper end 204a of each pillar or pin 204 may reduce the likelihood that a gap is formed between the outer or upper end 204a of each pillar or pin 204 and the surface profile of the mold tool 210 when the projecting portion 20 210a of the surface profile of the mold tool 210 makes contact with the area 208 of the surface of the base member 202. Thus, such a method may reduce the likelihood that any of the injected electrically insulating plastic material covers the outer or upper end 204a of each pillar or pin 204.

Such a method avoids any requirement to define or form any openings or windows in the housing 212 in order to expose the outer or upper end 204a of each pillar or pin 204 after the electrically insulating plastic housing material is cured. Such a method may therefore be more reliable than prior art methods for use in manufacturing optical emitter arrangements which require the definition or formation of openings or windows in a housing in order to expose the outer or upper end of an electrically conductive pillar or pin after the electrically insulating plastic housing material is cured.

One of ordinary skill in the art will understand that various modifications are possible to the optical emitter arrangements described above. For example, in a variant of the method of FIGS. 3A to 3F, each electrically conductive pillar or pin 104 may be unitary with the corresponding base element 103. For example, each electrically conductive pillar or pin 104 may be formed integrally or monolithically with the corresponding base element 103.

In a variant of the manufacturing method of FIGS. 3A to 3F, the silver epoxy 109 may be partially cured such that the silver epoxy 109 remains deformable before the surface profile of the mould tool 110 makes contact with the silver epoxy 109. Similarly, in a variant of the manufacturing method of FIGS. 4A to 4E, the silver epoxy 206 may be partially cured such that the silver epoxy 206 remains deformable before the surface profile of the mould tool 210 makes contact with the outer or upper end 204a of the corresponding pillar or pin 204.

In a further variant of the method of FIGS. 3A to 3F, rather than using deformable silver epoxy 109 at the outer or upper end 104a of the corresponding pillar or pin 104, the portions of the surface profile of the mold tool 110 which engage the silver epoxy 109 may be deformable. Each deformable portion of the surface profile of the mold tool 110 may be compressed when the deformable portion of the surface profile of the mold tool 110 is brought into engagement with the outer or upper end 104a of the corresponding pillar or pin 104. Similarly, in a variant of the manufacturing method of FIGS. 4A to 4E, rather than using silver epoxy 206 between the base end of each pillar or pin 204 and the corresponding base element 205, the portions of the surface profile of the mold tool 210 which engage the outer or upper ends 204a of the pillars or pins 204 may be deformable. Each deformable portion of the surface profile of the mold tool 210 may be compressed when the deformable portion of the surface profile of the mold tool 210 is brought into engagement with the outer or upper end 204a of the corresponding pillar or pin 204.

Although the method described with reference to FIGS. 3A to 3F or the method described with reference to FIGS. 4A to 4E may be used to manufacture a single optical emitter arrangement, it should be understood that either method may be used to manufacture a plurality of optical emitter arrangements simultaneously or in parallel.

Specifically, either method may comprise holding one or more electrically conductive further base members (not shown) and two or more electrically conductive further base elements (not shown) in a predetermined spatial relationship relative to each other and relative to the base member 102, 202 and each of the base elements 103, 203. One of skill in the art will understand that each of the one or more further base members, each of the two or more further base elements, the base member 102, 202 and each of the base elements 103, 203 may be fixed to a surface (not shown) in the predetermined spatial relationship.

The method may comprise providing two or more electrically conductive further projections (not shown), wherein each further projection extends in a direction away from a surface of a corresponding one of the further base elements and wherein each further projection terminates at a corresponding outer end. The method may comprise bringing a corresponding further projecting portion (not shown) of the surface profile of the mold tool 110, 210 into engagement with a corresponding area of a surface of each of the further base members whilst bringing other portions (not shown) of the surface profile of the mold tool 110, 210 into engagement with the outer ends of each of the further projections so that the void 113, 213 extends away from the surface of each of the further base members around each of the further projecting portions of the surface profile of the mold tool 110, 210 and the void 113, 213 extends away from the surface of each of the further base elements and around each further projection without extending over the outer end of each further projection. Injecting the electrically insulating plastic material into the void 113, 213 and curing the electrically insulating plastic material may then form one or more further electrically insulating housings, wherein each further housing extends away from the surface of the corresponding further base member so as to define a further space for accommodating a further optical emitter device, wherein the further space extends away from the area of the surface of the corresponding further base member, and wherein each further housing also extends away from the surface of each of the corresponding further base elements around each of the corresponding further projections without covering the outer end of each further projection.

The optical element may be configured differently to the optical element described above. The optical element may be configured to spatially modulate the light emitted by the optical emitter device. The optical element may be configured to spatially modulate the amplitude and/or phase of the light emitted by the optical emitter device. The optical element may be refractive. The optical element may comprise a lens. The optical element may comprise a plurality of lenses. The optical element may comprise a microlens array. The optical element may be diffractive. The optical element may comprise a diffraction grating.

The optical emitter device may comprise an optical source of any kind, for example a light emitting diode (LED) or a laser diode of any kind.

Methods of the present disclosure can be employed for use in the manufacture of optical emitter arrangements for use in many different applications including in projectors or in illuminators such as flood illuminators.

Although the disclosure has been described in terms of preferred embodiments as set forth above, it should be understood that these embodiments are illustrative only and that the claims are not limited to those embodiments. Those skilled in the art will be able to make modifications and alternatives to the described embodiments in view of the disclosure which are contemplated as falling within the scope of the appended claims. Each feature disclosed or illustrated in the present specification may be incorporated in any embodiment, whether alone or in any appropriate combination with any other feature disclosed or illustrated herein. In particular, one of ordinary skill in the art will understand that one or more of the features of the embodiments of the present disclosure described above with reference to the drawings may produce effects or provide advantages when used in isolation from one or more of the other features of the embodiments of the present disclosure and that different combinations of the features are possible other than the specific combinations of the features of the embodiments of the present disclosure described above.

The skilled person will understand that in the preceding description and appended claims, positional terms such as ‘above’, ‘along’, ‘side’, etc. are made with reference to conceptual illustrations, such as those shown in the appended drawings. These terms are used for ease of reference but are not intended to be of limiting nature. These terms are therefore to be understood as referring to an object when in an orientation as shown in the accompanying drawings.

Use of the term “comprising” when used in relation to a feature of an embodiment of the present disclosure does not exclude other features or steps. Use of the term “a” or “an” when used in relation to a feature of an embodiment of the present disclosure does not exclude the possibility that the embodiment may include a plurality of such features.

The use of reference signs in the claims should not be construed as limiting the scope of the claims.

### LIST OF REFERENCE NUMERALS

1 optical emitter arrangement;
2 base member;
3 base element
4 pillar or pin;
4a outer or upper end of pillar or pin;
5 lead frame;
6 silver epoxy;
8 area of surface of base member;
10 mold tool;
10a projecting portion of mold tool;
13 void;
13a gap;
12 housing;
14 window or opening in housing;
16 VCSEL;
20 wire-bonds;
30 optical system;
32 optical substrate;
34 optical safety element;
36 optical diffuser;
40 electrically conductive track or trace;
42 electrically insulating coating;
44 aperture;
50 silver epoxy;
101 optical emitter arrangement;
102 base member;
103 base element;
104 pillar or pin;
104a outer or upper end of pillar or pin;
105 lead frame;
106 silver epoxy;
107 projection;
107a outer or upper end of projection;
108 area of surface of base member;
109 silver epoxy;
110 mold tool;
110a projecting portion of mold tool;
112 housing;
113 void;
116 VCSEL;
120 wire-bonds;
130 optical system;
132 optical substrate;
134 optical safety element;
136 optical diffuser;
150 silver epoxy;
201 optical emitter arrangement;
202 base member;
203 base element;
204 pillar or pin;
204a outer or upper end of pillar or pin;
205 lead frame;
206 silver epoxy;
207 projection;
207a outer or upper end of projection;
208 area of surface of base member;
210 mold tool;
210a projecting portion of mold tool;
212 housing;
213 void;
216 VCSEL;
220 wire-bonds;
230 optical system;
232 optical substrate;
234 optical safety element;
236 optical diffuser; and
250 silver epoxy.

1. A method for use in manufacturing an optical emitter arrangement the method comprising:
holding an electrically conductive base member and two electrically conductive base elements in a predetermined spatial relationship;
providing two electrically conductive projections wherein each projection extends in a direction away from a surface of a corresponding one of the base elements and wherein each projection terminates at a corresponding outer end;
bringing a projecting portion of a surface profile of a mold tool into engagement with an area of a surface of the base member whilst bringing other portions of the surface profile of the mold tool into engagement with the outer ends of the projections so as to form a void that extends away from the surface of the base member around the projecting portion of the surface profile of the mold tool and that extends away from the surface of each of the base elements (103, 203) and around each projection without extending over the outer end of each projection;
injecting an electrically insulating plastic material into the void; and
curing the electrically insulating plastic material so as to form an electrically insulating housing that extends away from the surface of the base member so as to define a space for accommodating an optical emitter device, wherein the space extends away from the area of the surface of the base member, and wherein the housing also extends away from the surface of each of the base elements around each projection without covering the outer end of each projection.

2. The method of claim 1, wherein each projection is deformable and the method comprises compressing each projection between the surface profile of the mold tool and the corresponding base element when the surface profile of the mold tool makes contact with the outer end of each projection.

3. The method of claim 1, wherein each projection comprises deformable electrically conductive material.

4. The method of claim 1, wherein each projection comprises a rigid electrically conductive pillar or pin and deformable electrically conductive material.

5. The method of claim 4, wherein deformable electrically conductive material is located between a base end of each pillar or pin and the surface of the corresponding base element.

6. The method of claim 4, wherein each pillar or pin and the corresponding base element are unitary or each pillar or pin and the corresponding base element are formed integrally or monolithically.

7. The method of claim 4, wherein deformable electrically conductive material is located at, or defines, the outer end of each electrically conductive projection.

8. The method of claim 4, wherein the deformable electrically conductive material comprises a deformable electrically conductive adhesive material such as silver epoxy.

9. The method of claim 8, wherein the deformable electrically conductive adhesive material is uncured or only partially cured when the surface profile of the mold tool makes contact with the outer end of each projection.

10. The method of claim 8, comprising curing the deformable electrically conductive adhesive material after the surface profile of the mold tool makes contact with the outer end of each projection.

11. The method of claim 8, comprising curing the deformable electrically conductive adhesive material before curing the electrically insulating plastic material to form the electrically insulating housing.

12. The method of claim 1, comprising separating the mold tool from the housing after curing the electrically insulating plastic material and then applying electrically conductive adhesive material to the outer end of each projection.

13. The method of claim 12, comprising:
providing an optical system comprising an optical substrate and an optical safety element attached to the optical substrate, the optical safety element including an electrically conductive track or trace; and
bringing the optical system and the electrically conductive adhesive material at the outer end of each projection into engagement so that the electrically conductive track or trace makes contact with the electrically conductive adhesive material at the outer end of each projection.

14. The method of claim 13, wherein the optical system comprises an optical element attached to the optical safety element.

15. The method of claim 14, wherein at least one of:
the optical element comprises an optical diffuser;
the optical element is configured to spatially modulate a light emitted by the optical emitter device;
the optical element is configured to spatially modulate an amplitude and/or a phase of the light emitted by the optical emitter device;
the optical element is refractive;
the optical element comprises a lens;
the optical element comprises a plurality of lenses;
the optical element comprises a microlens array;
the optical element is diffractive; and
the optical element comprises a diffraction grating.

16. The method of claim 13, comprising attaching the optical system to the housing, for example using an adhesive.

17. The method of claim 1, wherein the optical emitter device comprises a light emitting diode (LED) or a laser diode such as a vertical cavity surface emitting laser (VCSEL) diode.

18. The method of claim 1, wherein the portions of the surface profile of the mold tool which are brought into engagement with the outer ends of the projections are deformable.

19. The method of claim 1, comprising:
holding one or more electrically conductive further base members and two or more electrically conductive further base elements in a predetermined spatial relationship relative to each other and relative to the base member and each of the base elements;
providing two or more electrically conductive further projections, wherein each further projection extends in a direction away from a surface of a corresponding one of the further base elements and wherein each further projection terminates at a corresponding outer end;
bringing a corresponding further projecting portion of the surface profile of the mold tool into engagement with a corresponding area of a surface of each of the further base members whilst bringing other portions of the surface profile of the mold tool into engagement with the outer ends of each of the further projections so that the void extends away from the surface of each of the further base members around each of the further projecting portions of the surface profile of the mold tool and the void extends away from the surface of each of the further base elements and around each further projection without extending over the outer end of each further projection; and
wherein injecting the electrically insulating plastic material into the void and curing the electrically insulating plastic material forms one or more further electrically insulating housings, wherein each further housing extends away from the surface of the corresponding further base member so as to define a further space for accommodating a further optical emitter device, wherein the further space extends away from the area of the surface of the corresponding further base member, and wherein each further housing also extends away from the surface of each of the corresponding further base elements around each of the corresponding further projections without covering the outer end of each further projection.

20. An optical emitter arrangement manufactured according to the method of claim 1 or a projector or an illuminator such as a flood illuminator comprising an optical emitter arrangement manufactured according to the method of claim 1.
